(19) United States
(12) Patent Application Publication
(10) Pub. No.: US 2024/0256222 A1
(43) Pub. Date: Aug. 1, 2024

(54) HIGH SPEED RIPPLE ADDER

(71) Applicant: Sehat Sutardja, Las Vegas, NV (US)

(72) Inventor: Sehat Sutardja, Las Vegas, NV (US)

(21) Appl. No.: 18/423,214

(22) Filed: Jan. 25, 2024

Related U.S. Application Data
(60) Provisional application No. 63/441,123, filed on Jan. 25, 2023.

(51) Int. Cl. G06F 7/506; H03K 19/00

(52) U.S. Cl. CPC G06F 7/506; H03K 19/00

(57) ABSTRACT

Apparatus and method to logically process signals representative of multiple-bit numbers include successively delaying applications of the bit-representative signals to logical processing stages from associated input registers by a delay interval between input registers that is substantially equal to the processing delay interval per bit-level of the logical processing stage. In this way, successively more significant bits of each of plural numbers being logically processed are validly available for processing at each bit-level logic stage after a delay. At least one of the bit-representative signals is inverted prior to the input registers or prior to processing by the logical processing stage. The delay is reduced by omitting an inverting function in a carry circuit associated with at least one logical processing stage. Similarly, output registers for latching the logic output of each bit-level logic stage are clocked at successively delayed intervals substantially equal to the processing delay interval.

### 1. FIELD OF THE INVENTION

The invention relates to ripple adders, and in particular a ripple adder system with an alternating binary number system.

### 2. RELATED ART

This prior art is presented to establish a foundation to aid in understanding of the improvements over the prior art. FIG. 1 illustrates an exemplary prior art ripple carry type adder. Shown is an arithmetic logic stage, such as a redundant adder 9 or other adder of conventional design such as a carry-shift added, or Manchester carry adder or the like, having a plural number of inputs for the number n of significant bits applied thereto from each input register 11, 13. The resultant arithmetic logical output (e.g., the sum of A+B) of n bits is supplied to an output register 15 which may serve as an input register in a successive stage or logic level of concatenated arithmetic processing of plural numbers A, B . . . N.

FIG. 2 illustrates a simplified block schematic diagram of one embodiment of the present invention in which a plurality of conventional ripple-carry logic stages (e.g., summing elements) 17-19 at one logic level of arithmetic processing are each disposed to receive respective significant bits Ø . . . n of each input number, shown as inputs A, B. Each logic stage 17-19 receives a carry input Ci to produce a resultant or summation output defined as S_{Ø}, S₁ . . . Sₙ, and also provides a carry output C_{O} for application to the successively more-significant bit-level logic stage. Each of the bit-level inputs A_{Ø}, A₁, . . . Aₙ and B_{Ø}, B₁, . . . Bₙ is supplied from a corresponding bit-level register 21-23 and 25-27 in which the bit-level signals are latched or stored in conventional matter. Each of the resultant or summation outputs S_{Ø}., S₁, . . . Sₙ is supplied to corresponding bit-level output registers 29-31 to be latched or stored therein in conventional manner, all in an example of 8-bit logic operation. The output registers 29-31 may serve as input registers in a subsequent logic level of logic processing with additional multi-bit numbers X, Y . . . N in a similar manner as described herein. Each of the bit-level input registers 21-23 and 25-27, and output registers 29-31 are clocked in conventional manner, ideally from the same source (not shown) of clock signals 34. The clock signals per bit level are illustrated for convenience as being passed through, or beyond each register, and forward the next bit-level register.

Delay elements 33 are interposed between each of the bit-level input registers (and 37 between each output register 29-31, which may serve as input registers in a successive logic level). Each of the delay elements 33, 37 substantially approximates the delay interval (typically, two clock intervals which match the two delay cycles associated with prior art carry circuits) associated with each logic stage 17-19 to produce a logic carry output (and an overflow) for application to the next more-significant, bit-level logic stage 17-19. Such delay elements 33, 37 may each include two inverters in one embodiment of the invention to match the two clock cycle delays inherent in the carry circuits in each of the logic stage 17-19. In general, an initial carry input (if any, for example, from a previous logic level) may be applied to the least significant bit-level logic stage 17.

In the manner described above, the delays through the input registers are substantially matched to the delays associated with the logic stages 17-19 in generating resultant carry outputs (if any) for application to the logic stages corresponding to the next more significant bit of multi-bit input numbers. This essentially limits the delays involved at one logic level of concatenated logic processing to the delays associated with successively latching the significant bits of the input numbers into the corresponding input registers, and to the additional delay interval of the arithmetic logical processing of the significant bits of each input number through the corresponding logic stages 17-19. As illustrated at the bottom of FIG. 2, the clock signals provided to each bit-level register 25-27 and 29-31 are successively delayed (t₁, t₂, . . . ) from the initial clock input t_{Ø}. by the delay elements 33, 37 that are interposed in the clock lines between successive bit-level registers. Since the more significant bits are commonly not available, or are not valid until successively later intervals, the additional clock delay elements 33, 37 may be conveniently introduced in the manner previously described between the successive stages of the input registers 21-23 and 25-27 (and of the output registers 29-31) corresponding to the significant bits of the applicable numbers being arithmetically processed to thereby obviate problems commonly associated with conventional parallel-processing of the input numbers. Therefore, the arithmetic logical processing apparatus and method according to the embodiment of FIG. 2 provides incremental delays between the latching intervals of successive input registers corresponding to the significant bits of input numbers to be arithmetically processed.

The prior art described above is disclosed in U.S. Patent Number USRE37335E1 assigned application Ser. No. 09/585,343, filed on Jun. 2, 2000, which is a re-issued patent to U.S. Pat. No. 5,764,718, U.S. Patent Number USRE37335E1 which is incorporated herein by reference in its entirety.

It is also understood that modern artificial intelligence (AI) and wired and wireless digital signal processors are quite unique in terms of their precision needs in their arithmetic logic circuit. While normal computers may need 64 bits or even 128 bits of precision, these massively parallel devices need only around 8-12 bits of precision. With this level of required precision, the traditional carry look-ahead arithmetic logic is overkill, and more importantly, a waste of silicon area and energy consumption.

On the other hand, traditional ripple carry adder arithmetic, such as that referenced above, is too slow for most applications. The reason is because ripple adders have worse case propagation delay which increases linearly with the number of precision bits that need to be handled and because CMOS logic is inherently inverting in nature. In order to function, a ripple adder carry circuit requires, at the minimum, two gate delays.

### SUMMARY

To overcome the drawbacks of the prior art and provide additional benefits, a logic circuit is disclosed that comprises a plurality of logic stages, each having plural signal inputs and a carry input for logically processing applied signals within a processing delay interval to produce an output representing selected significant bits of multi-bit numbers, and a carry output representing a logic overflow of the logically-processed applied signals, wherein at least one carry output is inverted in relation to the carry input thereby reducing the processing delay interval. Also part of the logic circuit is a plurality of input registers for each of the multiple bits of multiple-bit numbers. Each has a clock input and an input for receiving a selected bit of a multi-bit number for supplying, on an output, a signal representative of the selected bit to an input of a corresponding logic stage. This occurs in response to a clock signal applied to the clock input thereof, such that the input to at least one input register is inverted as compared to the output of the at least one register. Also included is a delay element connected between clock inputs of each of the input registers for each of the multiple-bit numbers to successively delay application of clock signals to the clock inputs of successively-oriented input registers for the selected bits of each of the multiple-bit numbers. The amount of delay of the delay element is related to the reduced processing delay of the logic stages.

In one embodiment, the at least one carry output is inverted in relation to the carry input due to the at least one logic stage not inverting its output, thereby resulting in the at least one carry output being inverted, which reduces delay associated with the omitted inverting function. It is also contemplated that instead of the input to at least one input register being inverted as compared to the output of the at least one register, at least one logic stage inverts the output from an input register prior to processing by the at least one logic stage. In one configuration, the delay element delays application of clock signals to successively-oriented input registers by substantially the processing delay interval of the corresponding logic stage. In one embodiment, each of the carry outputs of each of the logic stages is supplied to a carry input of a successively-oriented logic stage substantially without delay. The logic circuit may also comprise a plurality of output registers, each having a clock input and having an input connected to receive an output from a corresponding logic stage and being operable in response to a clock signal applied thereto to latch the output of the corresponding logic stage. And, a delay element connected between clock inputs of each of the output registers to successively delay application of clock signals to the clock inputs of successively-oriented output registers for latching therein selected bits of a multiple-bit number.

Also disclosed is a method for reducing delay associated with processing a plurality of multi-bit numbers is a plurality of logic stages, each having plural signal inputs and a carry input for logically proceeding applied signals within a processing delay interval to produce an output representing selected significant bits of multi-bit numbers, and a carry output representing a logic overflow of the logically-processed applied signals. In operation, this method latches a plurality of multiple bit signals representative of multiple-bit numbers for selective application when clocked to a corresponding logic stage. Prior to clocking to the logic stage or prior to processing by the logic stage, inverting at least one of the multiple bit signals, and supplying a carry output from a logic stage to a carry input of a successive logic stage following a processing delay interval. The at least one carry output is inverted in relation to the carry input due to omission of an inverting function in a carry circuit of at least one logic stage. This method also selectively delays substantially by the processing delay interval the clocking of the latched multiple bit signals to the logic stages to successively delay logic processing of the applied signals to produce associated output and carry output within a processing delay interval in each logic stage, wherein at delaying is reduced due to the omission of an inverting function in a carry circuit of at least one logic stage.

In one embodiment, the method further comprises latching the output of each logic stage for selective access when clocked and successively delay the clocking of access to each latched logic stage output substantially by the processing delay interval to accumulate latched outputs representative of a multiple bit number after a plural number of processing delay intervals. Omitting the inverting function in the carry circuit occurs because of an elimination of an inverter in the carry circuit, which reduces processing time required for the logic stage, which in turn reduces the processing delay interval.

Also disclosed is a logic circuit having reduced delay that comprises a plurality of input registers, each having a clock input configured to receive a clock signal and having an input connected to receive input signals and being operable in response to the clock signal applied thereto to output the input signals into a corresponding logic stage. Also part of this embodiment is a a plurality of logic stages. Each hasg plural signal inputs and a carry input for logically processing applied signals within a processing delay interval to produce an output representing selected significant bits of multi-bit numbers. The carry output representing a logic overflow of the logically-processed applied signals, such that for at least one of the plurality of logic stages the input signals are inverted prior to receipt at the logic stage or by the logic stage, prior to processing by the logic stage. A carry circuit within the logic stages configured to generate the carry output, such that for at least one logic stage the carry output is inverted as compared to the carry input. A plurality of output registers is also provided, each having a clock input and having an input connected to receive an output from a corresponding logic stage. The output registers being operable in response to a clock signal applied thereto to latch the output of the corresponding logic stage. Also provided is a delay element, having a reduced delay due to inverted output of the carry circuit, connected between clock inputs of each of the input registers and output registers to successively delay application of clock signals to the clock inputs of successively-oriented output registers for latching therein selected bits of a multiple-bit number.

In one embodiment, the delay element delays application of clock signals to successively-oriented output registers by substantially the processing delay interval of the corresponding logic stage. It is also contemplated that each of the carry outputs of each of the logic stages is supplied to a carry input of a successively-oriented logic stage substantially without delay. The delay element also delays application of clock signals to successively-oriented output registers by substantially the processing delay interval of the corresponding logic stage.

Also disclosed is a method for processing a plurality of multi-bit numbers in a plurality of logic stages, each having plural signal inputs and a carry input for logically processing applied signals within a processing delay interval to produce an output representing selected significant bits of multi-bit numbers, and a carry output representing a logic overflow of the logically-processed applied signals. In one embodiment, the method comprising the steps of latching a plurality of multiple bit signals representative of multiple-bit numbers for selective application when clocked to a corresponding logic stage and then processing the multiple bit signals with the corresponding logic stage, such that at least one of the multiple bit signals are inverted prior to processing by the corresponding logic stage. The method then latches the output of each logic stage for selective access when clocked and supplies a carry output from a logic stage to a carry input of a successive logic stage following a processing delay interval. The at least one carry input or carry output is inverted due to the logic stage carry circuit omitting an output inverter thereby providing a carry output which is an inverted version the carry input. This method also successively delays the clocking of access to each latched logic stage output substantially by the processing delay interval to accumulate latched outputs representative of a multiple bit number after a plural number of processing delay intervals.

In one embodiment, this method the step of successively delaying is performed by a delay element and each delay element delays the application of the clock signal by a delay which corresponds to the processing of the at least one applied signal by the corresponding logic stage. It is also contemplated that the step of successively delaying is performed by a delay element and the delay element delays the application of the clock signal by a delay which corresponds to a time required for the corresponding logic stage to produce a logic carry output. Each of the plurality of logic stages may provide its carry output to a carry input of a subsequent logic stage. The step of processing the multiple bit signals, each of the logic stages outputs a summation signal and the carry input.

### BRIEF DESCRIPTION OF THE DRAWINGS

The components in the figures are not necessarily to scale, emphasis instead being placed upon illustrating the principles of the invention. In the figures, like reference numerals designate corresponding parts throughout the different views.

FIG. 1 is a block schematic diagram of a conventional prior art ripple-carry logic circuitry.

FIG. 2 is a block schematic diagram of a prior art ripple-carry logic circuitry.

FIG. 3 illustrates an example embodiment of an improved ripple adder circuit with reduced delay time.

FIG. 4A illustrates an exemplary numbering system using both positive and negative values in the numbering system, such as for use in an adder or multiplier circuit.

FIG. 4B illustrates a truth table of the positive and negative versions of an adder logic.

FIG. 5 shows an exemplary carry circuit with minimized delay.

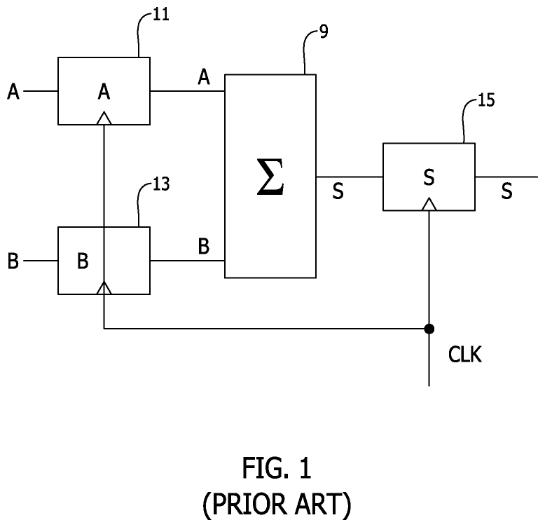

### DETAILED DESCRIPTION

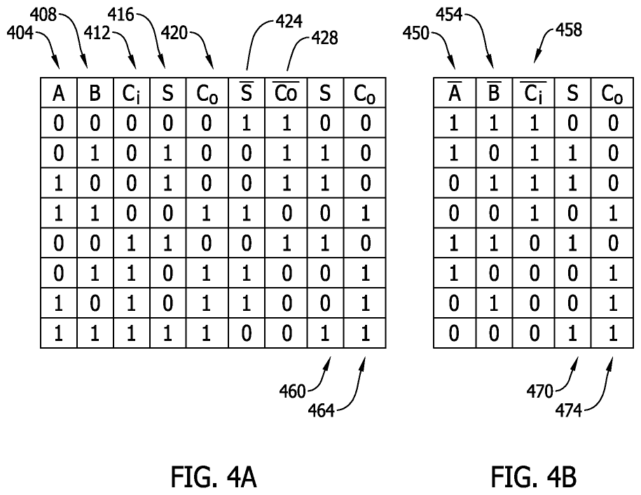

To reduce the propagation delay in a ripple adder arithmetic circuit, an alternating binary number system is proposed. Instead of a numbering system of all positive or negative logic values (active highs or active lows), both positive and negative values are used in the numbering system in a given adder or multiplier circuit, such as for example whereas adjacent bits use the opposite logic high and logic low values. FIGS. 4A and 4B illustrate an exemplary numbering system using both positive and negative values, such as for use in an adder or multiplier circuit. For example, even data bits could be assigned with active positive values, while odd data bits are assigned with active negative values (or vice versa).

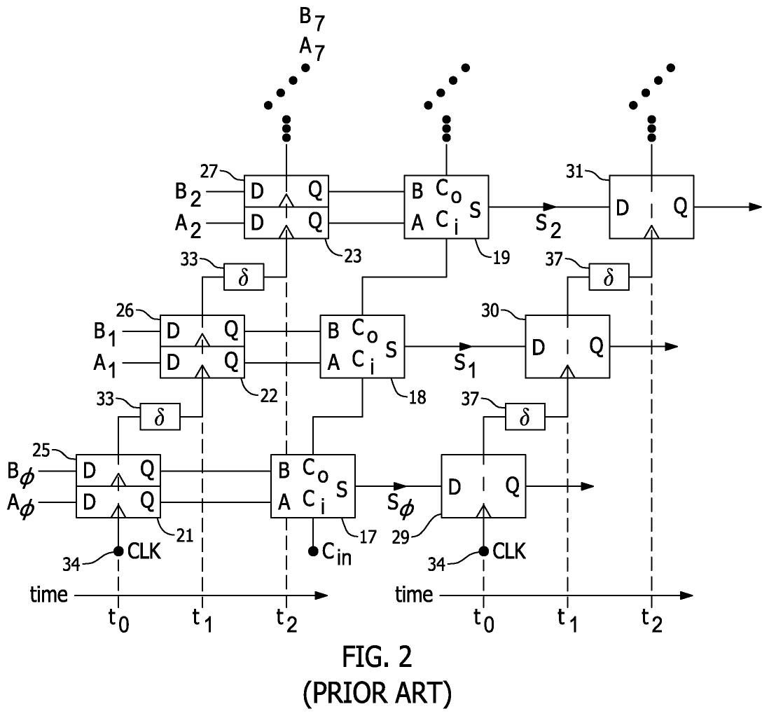

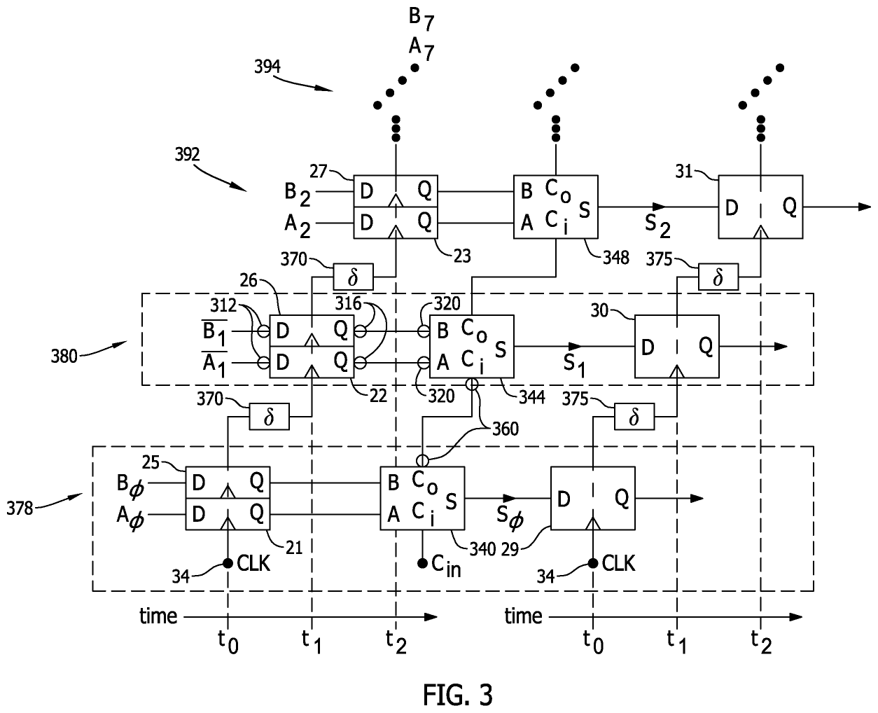

FIG. 3 illustrates an example embodiment of an improved ripple adder circuit with reduced delay time. As compared to FIG. 2, identical or similar elements are identified with identical reference numbers. The aspects of FIG. 2, which are discussed above, are not discussed again. Differing from the prior art shown in FIG. 2, the inputs B₁ and A₁ are inverted, and as such are designated as B₁ bar and A₁ bar. The inversion, such as by using an inverter, can be placed at one of the inverter locations 312, 316, 320. By placing inverters at one of these locations 312, 316, 320 (or other location that performs an equivalent inversion), the signal B₁ and A₁ are thereby inverted when being presented to the ripple-carry logic stages (e.g., summing elements) 344. Note that the input signal for a particular row would only be inverted once, such that only one of the locations 312, 316, 320 would be inverting. The inversion could be built into device 26 or 344. The inverted status of A₁ bar and B₁ bar continues throughout the signal path. FIGS. 4A and 4B discuss the inversion in more detail. Any manner of establishing the inversion is contemplated, such as an inverter at any one of the inverter locations 312, 316, 320. Alternatively, the signals B₁ and A₁ may be inverted prior to receipt at the bit level register 26. As discussed below, there is an alternating inversion pattern of the inputs to the registers (or register outputs) in the rows 378, 380, 392, throughout the additional rows 394. For example, the inputs to row 380 and the inputs to the row after row 392 may inverted, and this alternating inversion pattern continues through the remaining rows 394. Alternatively, the inputs to row 378, 392 are inverted and this pattern may continue through the remaining rows, while the inputs to row 380 are not inverted.

In addition to the signals B₁ and A₁ being inverted, inversions may occur at one of the locations 360. This provides an inverted signal to the input port Cᵢ of summing element 344. Thus, the clock inputs signal Cᵢₙ is not inverted, but the input to the Cᵢ port is inverted as compared to the prior art. Thus, Cᵢ becomes Cᵢ bar. This signal inversion occurs due to a change in the carry circuitry within the summing elements 340, 344, 348. In contrast to the prior art, which inverted every output Cₒ of the summing elements 340, 344, 348, the disclosed improvement does not incorporate an additional inverting function of the carry circuit within the summing elements. Thus, the carry circuit output will be inverted in relation to the carry circuit input, and the carry circuit does not include an additional inverter to invert the carry circuit output.

Omitting the additional inverting function in the carry circuit (that was present in the prior art) provides a significant improvement over the prior art by reducing the delay (processing time) associated with the summing function performed by the summing elements 340, 344, 348. Traditional carry circuits have, at a minimum, two clock cycle delay, one of which is attributable to the inverting function within the carry circuit. CMOS implementations are inverting in nature, and thus require an additional inverter to generate an output that was not inverted as compared to the input. As a result, removing the second inverting function in the carry circuit of the summing element reduces the delay by 40% to 50% depending on the implementation of the carry circuit. Thus, the circuit is almost twice as fast. This delay reduction increases the speed of the adding function of the adder circuit. In the case of a 32-bit summing element, this equates to saving a 13 to 16 clock cycles, which is a significant improvement over the prior art.

Also shown in FIG. 3 are delays 370, 375 which differ from that shown in FIG. 2. The delays 370, 375 establish a shorter delay, such as about half, as compared to the delay associated with the delays 33, 37 shown in FIG. 2. The delay is reduced because the delay of each carry circuit is reduced as described herein. It is also contemplated that the circuits disclosed herein may include low power flip-flops thereby further reducing power consumption, such as an additional 50%.

Thus, FIG. 3 shows an improvement over the previously disclosed patent (U.S. RE37335E1) for building a ripple adder logic circuit in the presence of input and output registers with a staggered clocking technique. With the alternating binary numbering system, by inverting the polarity of the even or odd register bits the disclosed circuit is a pipelined adder logic with practically half of the overall gate delays. Accordingly, the delta value (delta as defined in the prior patent filing—U.S. RE37335E1) used in the staggered clock delay path could be approximately halved as well. This is achieved by using only an inverter for the delay circuitry (instead of the original slower non-inverting buffer) as well as using registers with the new alternating clock input polarity.

FIG. 4A illustrates an exemplary numbering system using both positive and negative values in the numbering system, such as for use in an adder or multiplier circuit. With an alternating-binary numbering system a ripple carry adder circuit may have only a single CMOS gate delay in the ripple path. FIGS. 4A and 4B illustrate a truth table of the positive and negative versions of an adder logic. The following are all referenced to FIG. 3. Column 404 represents the A value input. Column 408 represents the B value input. Column 412 represents the Cᵢ value input. Column 416 represents the S value input. Column 420 represents the Cₒ value input. Column 424 represents the S bar value input (which is an inverted S value). Column 428 represents the Cₒ bar value input (which is an inverted Cₒ value). As shown in the table, for all the various permutations of A, B, and Cᵢ, the outputs S and Co, of the summing element, are shown in columns 416, 420, as would be output by the circuit of FIG. 3. Columns 460 and 464 provide the S and C₀ value which are not inverted. These columns provide logic values which are opposite that of columns 424, 428.

In comparison, FIG. 4B illustrates exemplary numbering system using inverted values of the inputs to the summing elements, such as presented to summing element 344 (FIG. 3). Columns 450, 454, 458, represent A bar, B bar and Cᵢ bar and are thus inverted as compared to columns 404, 408, 412 of FIG. 4A. As can be seen, the resulting values for S and Co are the same as in columns 416, 420 even though the inputs (A bar, B bar and Cᵢ bar) are inverted. This proves that the function of the circuit does not change even when the data input (A bar, B bar, and Cᵢ bar) is inverted, and when using these inverted signal inputs, a clock delay is saved (due to omission of an inverter) within each carry circuit and within the summing element. For example, it can be seen that when comparing columns 460, 464 to columns 470, 474, the same values for S and Cₒ exist even when the inputs A bar, B bar and Cᵢ bar are inverted as shown in FIG. 4B.

After analyzing the table of the positive and negative versions of an adder logic as shown in FIGS. 4A and 4B, it is disclosed to use a ripple adder logic circuit implementation having only a single stage gate delay property. By inverting all input polarities, the output polarities are automatically inverted.

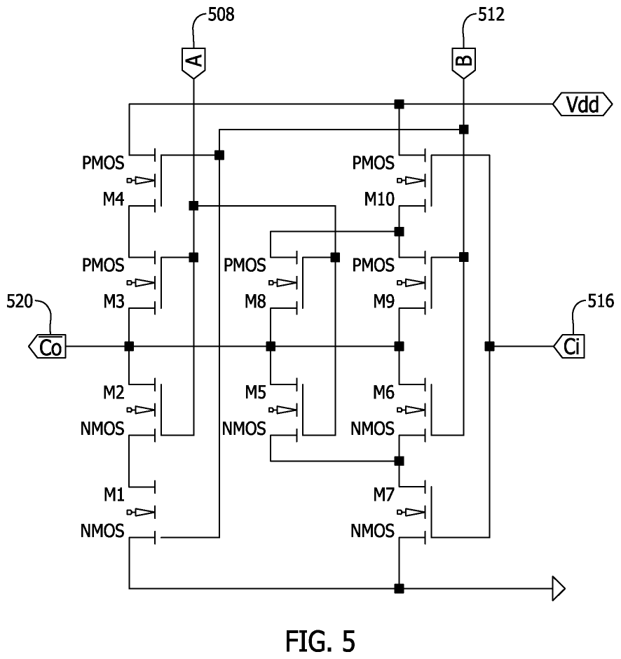

FIG. 5 illustrates an example embodiment of a carry function circuit. In this embodiment, the delay is reduced from two clock cycles to one clock cycle. This circuit implements the table shown in FIG. 4B. This circuit has an A signal input 508 and a B signal input 512, which correspond to the inputs B₁ and A₁ shown in FIG. 3. The carry function circuit also includes the carry input Cᵢ 516 and the carry output Cₒ 520. Because this circuit does not have an inverting nature, thereby avoiding the second clock cycle delay associated with the additional inverter in the carry circuit, the carry output Cₒ is inverted as compared to the input. This does not have an unwanted effect on circuit operation (as established by FIG. 4B) yet saves a clock cycle of delay.

The inputs of FIG. 5 (for row 378 in FIG. 3) are the B_{Ø} and A_{Ø} inputs 508, 512, which are not inverted, and the carry input Cᵢₙ 516 is not inverted, while the carry output Cₒ 520 is inverted. However, in this embodiment, for processing row 380 (FIG. 3) for the second bit, the B_{Ø} and A_{Ø} inputs 508, 512 are inverted, and would be designated as B_{Ø} bar and A_{Ø} bar, and the carry input Cᵢₙ 516 is inverted since it was received from summing element 340, while the carry output Cₒ 520 from summing element 344 is not inverted. This pattern would repeat up through the additional rows for each additional bit. Thus, the inputs to processing row 392 would not be inverted, but the subsequent row would be inverted. This is designated as an alternating inversion of the registers. For example, it is also possible for the inputs to row 378 and 392 to be inverted, while the inputs to row 380 to not be inverted, and this alternating inversion pattern would continue through the rest of the rows, such as up to inputs A₇, B₇. This circuit of FIG. 5 is exemplary, and it is contemplated that other embodiments may be created which provide the benefits discussed herein, namely one clock cycle per carry operation instead of the prior art two clock cycle per carry operation.

### Benefits Over Prior Art

Ripple arithmetic circuits configured as disclosed herein can operate at practically twice the operating frequencies of the prior art ripple arithmetic circuit. Meanwhile the ultra-low-glitch energy property of staggered register clocking, as disclosed in the original patent filing, (U.S. Pat. RE37335E1) is maintained. By closely matching the clocking delays between the adjacent data registers it is possible to practically eliminate the false logical transitions in the overall adder circuit. This results in absolutely the lowest power (meaning the highest possible efficiency) adder circuit. The delay of the adder circuit could be slightly longer than the delay of the inverter buffer in the clock path. One possible way of matching the clocking delay circuit is to size down the inverter delay circuit in the clock path. This would ultimately further reduce the power required for clocking and simplify the global clocking distribution network complexity.

The inverting ripple carry stage is almost twice as fast as the non-inverting counterpart. As a result, it is now possible, using the disclosed innovation, to create adder or even multiplier circuits almost twice as fast as prior art implementations, such as that disclosed in the FIG. 2.

The disclosed circuit would still maintain the low transition energy of the prior art adder circuit as the transistors are only switching at most once during a given clock cycle. This is the result of matching the delay of the staggered clocking of the DFF to the delay of the carry ripple circuit.

The circuit of FIG. 5 reduces gate delay from two to one and this in turn reduces the required switching for the carry function. As a result, power consumption is reduced by reducing gate loading for the prior stage, such as the flop, which allows for faster operation due to lower capacitive loading from the next stage.

U.S. Patent Number USRE37335E1 assigned application Ser. No. 09/585,343, filed on Jun. 2, 2000, which is a re-issued patent to U.S. Pat. No. 5,764,718. U.S. Patent Number USRE37335E1 is incorporated herein by reference in its entirety.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

While various embodiments of the invention have been described, it will be apparent to those of ordinary skill in the art that many more embodiments and implementations are possible that are within the scope of this invention. In addition, the various features, elements, and embodiments described herein may be claimed or combined in any combination or arrangement.

What is claimed is:

1. A logic circuit comprising:
a plurality of logic stages, each having plural signal inputs and a carry input for logically processing applied signals within a processing delay interval to produce an output representing selected significant bits of multi-bit numbers, and a carry output representing a logic overflow of the logically-processed applied signals, wherein at least one carry output is inverted in relation to the carry input thereby reducing the processing delay interval;
a plurality of input registers for each of the multiple bits of multiple-bit numbers, each having a clock input and having an input for receiving a selected bit of a multi-bit number for supplying, on an output, a signal representative of the selected bit to an input of a corresponding logic stage in response to a clock signal applied to the clock input thereof, wherein the input to at least one input register is inverted as compared to the output of the at least one register; and
a delay element connected between clock inputs of each of the input registers for each of the multiple-bit numbers to successively delay application of clock signals to the clock inputs of successively-oriented input registers for the selected bits of each of the multiple-bit numbers, wherein an amount of delay of the delay element is related to the reduced processing delay of the logic stages.

2. The logic circuit according to claim 1 wherein the at least one carry output is inverted in relation to the carry input due to the at least one logic stage not inverting its output, thereby resulting in the at least one carry output being inverted, which reduces delay associated with the omitted inverting function.

3. The logic circuit according to claim 1 wherein instead of the input to at least one input register being inverted as compared to the output of the at least one register, at least one logic stage inverts the output from an input register prior to processing by the at least one logic stage.

4. The logic circuit according to claim 1 wherein the delay element delays application of clock signals to successively-oriented input registers by substantially a same delay amount as the processing delay interval of the corresponding logic stage.

5. The logic circuit according to claim 1 wherein each of the carry outputs of each of the logic stages is supplied to a carry input of a successively-oriented logic stage substantially without delay.

6. The logic circuit according to claim 1 wherein for the plurality of input registers and plurality of logic stages are arranged in rows and for alternating rows, the inputs to the logic stages are inverted as compared to the inputs to the input registers, while for other alternating rows the inputs to the logic stages are not inverted as compared to the inputs to the input registers.

7. The logic circuit according to claim 1 comprising:
a plurality of output registers, each having a clock input and having an input connected to receive an output from a corresponding logic stage and being operable in response to a clock signal applied thereto to latch the output of the corresponding logic stage; and
a delay element connected between clock inputs of each of the output registers to successively delay application of clock signals to the clock inputs of successively-oriented output registers for latching therein selected bits of a multiple-bit number.

8. A method for reducing delay associated with processing a plurality of multi-bit numbers is a plurality of logic stages, each having plural signal inputs and a carry input for logically proceeding applied signals within a processing delay interval to produce an output representing selected significant bits of multi-bit numbers, and a carry output representing a logic overflow of the logically-processed applied signals, the method comprising:
latching a plurality of multiple bit signals representative of multiple-bit numbers for selective application when clocked to a corresponding logic stage;
prior to clocking to the logic stage or prior to processing by the logic stage, inverting at least one of the multiple bit signals;
supplying a carry output from a logic stage to a carry input of a successive logic stage following a processing delay interval, wherein at least one carry output is inverted in relation to the carry input due to omission of an inverting function in a carry circuit of at least one logic stage; and
selectively delaying substantially by the processing delay interval the clocking of the latched multiple bit signals to the logic stages to successively delay logic processing of the applied signals to produce associated output and carry output within a processing delay interval in each logic stage, wherein at delaying is reduced due to the omission of an inverting function in a carry circuit of at least one logic stage.

9. The method according to claim 8 comprising:
latching the output of each logic stage for selective access when clocked; and
successively delay the clocking of access to each latched logic stage output substantially by the processing delay interval to accumulate latched outputs representative of a multiple bit number after a plural number of processing delay intervals.

10. The method according to claim 8 wherein omitting the inverting function in the carry circuit eliminates an inverter in the carry circuit, which reduces processing time required for the logic stage, which in turn reduces the processing delay interval.

11. The method according to claim 8 wherein the inverting at least one of the multiple bit signals alternates between rows of logic stages.

12. A logic circuit having reduced delay comprising:
a plurality of input registers, each having a clock input configured to receive a clock signal and having an input connected to receive input signals and being operable in response to the clock signal applied thereto to output the input signals into a corresponding logic stage;
a plurality of logic stages, each having plural signal inputs and a carry input for logically processing applied signals within a processing delay interval to produce an output representing selected significant bits of multi-bit numbers, and a carry output representing a logic overflow of the logically-processed applied signals, wherein for at least one of the plurality of logic stages the input signals are inverted prior to receipt at the logic stage or by the logic stage, prior to processing by the logic stage;
a carry circuit within the logic stages, the carry circuit generating the carry output, such that for at least one logic stage the carry output is inverted as compared to the carry input;
a plurality of output registers, each having a clock input and having an input connected to receive an output from a corresponding logic stage and being operable in response to a clock signal applied thereto to latch the output of the corresponding logic stage; and
a delay element, having a reduced delay due to inverted output of the carry circuit, connected between clock inputs of each of the input registers and output registers to successively delay application of clock signals to the clock inputs of successively-oriented output registers for latching therein selected bits of a multiple-bit number.

13. The logic circuit according to claim 12 wherein the delay element delays application of clock signals to successively-oriented output registers by substantially the processing delay interval of the corresponding logic stage.

14. The logic circuit according to claim 12 wherein each of the carry outputs of each of the logic stages is supplied to a carry input of a successively-oriented logic stage substantially without delay.

15. The logic circuit according to claim 12 wherein the delay element delays application of clock signals to successively-oriented output registers by substantially the processing delay interval of the corresponding logic stage.

16. A method for processing a plurality of multi-bit numbers in a plurality of logic stages, each having plural signal inputs and a carry input for logically processing applied signals within a processing delay interval to produce an output representing selected significant bits of multi-bit numbers, and a carry output representing a logic overflow of the logically-processed applied signals, the method comprising the steps of:
latching a plurality of multiple bit signals representative of multiple-bit numbers for selective application when clocked to a corresponding logic stage;
processing the multiple bit signals with the corresponding logic stage, such that at least one of the multiple bit signals are inverted prior to processing by the corresponding logic stage;
latching the output of each logic stage for selective access when clocked;
supplying a carry output from a logic stage to a carry input of a successive logic stage following a processing delay interval, wherein at least one carry input or carry output is inverted due to the logic stage carry circuit providing a carry output which is an inverted version the carry input; and
successively delaying the clocking of access to each latched logic stage output substantially by the processing delay interval to accumulate latched outputs representative of a multiple bit number after a plural number of processing delay intervals.

17. A method according to claim 16, wherein successively delaying is performed by a delay element, and each delay element delays the application of the clock signal by a delay which corresponds to the processing of the at least one applied signal by the corresponding logic stage.

18. A method according to claim 16, wherein successively delaying is performed by a delay element and the delay element delays the application of the clock signal by a delay which corresponds to a time required for the corresponding logic stage to produce a logic carry output.

19. A method according to claim 16, wherein each of the plurality of logic stages provides its carry output to a carry input of a subsequent logic stage.

20. A method according to claim 16, wherein in the step of processing the multiple bit signals, each of the logic stages outputs a summation signal and the carry input.
